(19) United States
(12) Patent Application Publication
(10) Pub. No.: US 2021/0141176 A1
(43) Pub. Date: May 13, 2021

(54) OPTICAL TRANSCEIVER

(71) Applicant: Delta Electronics, Inc., Taoyuan City (TW)

(72) Inventors: Chen-Mao Lu, Taoyuan City (TW); Wen-Ching Chung, Taoyuan City (TW); Li-Hua Su, Taoyuan City (TW)

(21) Appl. No.: 16/781,075

(22) Filed: Feb. 4, 2020

(30) Foreign Application Priority Data
Nov. 13, 2019 (CN) 201911104471.6

(51) Int. Cl. G02B 6/42; H05K 5/02; H05K 9/00; H05K 5/00

(52) U.S. Cl. CPC G02B 6/4277; H05K 5/023; G02B 6/4278; G02B 6/428; H05K 5/0052; H05K 5/006; H05K 5/0008; H05K 9/0058

(57) ABSTRACT

The present invention provides an optical transceiver including a first housing, a second housing, a printed circuit board, a handle member and an elastic body. The first housing and the second housing are assembled with each other as a main body, and form an accommodation space, a first handle-guiding groove and a second handle-guiding groove. The first handle-guiding groove and the second handle-guiding groove are respectively located on two opposite sides of the main body. The printed circuit board is accommodated within the accommodation space. The handle member has a first arm and a second arm respectively received in the first handle-guiding groove and the second handle-guiding groove. The elastic body is received in an elastic-body-receiving slot of the first housing. None side of the elastic-body-receiving slot is formed by the second housing, or the elastic-body-receiving slot is a non-linear slot.

### FIELD OF THE DISCLOSURE

The present disclosure relates to an optical transceiver applicable to an optical fiber communication system, and more particularly to an optical transceiver for enhancing the protection from electromagnetic interference.

### BACKGROUND OF THE DISCLOSURE

With the rapid development of computer systems and related peripheral devices in recent years, the speed of information transmission is increased to cope with the implementation of high-complexity tasks, such as digital signal transmission and image analysis. Under the demand, the optical fiber communication technology is provided to meet it, which can be applied to long-distance or short-distance signal transmission. Consequently, the high-speed optical signal is utilized to replace the conventional electrical signal, so as to achieve the purpose of increasing information transmission speed.

The optical fiber communication system generally includes an optical transceiving assembly installed in the electronic communication device to provide a signal transmission function between the electronic devices. In order to increase the flexibility of the system design and the maintenance convenience, the optical transceiving assembly further includes an optical transceiver, which is detachably plugged into a corresponding connection slot of the electronic communication device. In that, the optical transceiver and the corresponding connection slot typically include a latch mechanism for locking the optical transceiver with the corresponding connection slot or detaching the optical transceiver from the corresponding connection slot.

A conventional optical transceiver includes a housing in combination with an elastic body to accommodate a printed circuit board for photoelectric conversion. Since the assembly of the housing assembly and the elastic body is easy to form a structural joint gap therebetween, when the high-speed long-wavelength light is transmitted and received, the electromagnetic interference of the electronic components on the printed circuit board is easily caused.

Therefore, there is a need of providing an optical transceiver to address the above issues encountered by the prior arts.

### SUMMARY OF THE DISCLOSURE

An object of the present disclosure is to provide an optical transceiver. By disposing a latch handle member on the outer side of a housing assembly without penetrating the housing assembly, it is beneficial to prevent the electronic components disposed on the printed circuit board accommodated within the housing assembly from generating the electromagnetic interference (EMI) leakage, so that EMI shielding is enhanced.

Another object of the present disclosure is to provide an optical transceiver. An elastic body providing the elastic force in the latching mechanism is installed through an opening of the latch handle member into an elastic-body-receiving slot constructed by the latch handle member and the housing assembly. The elastic body is effectively limited in the elastic-body-receiving slot. It is beneficial to prevent the elastic body from bouncing out during the latching operation, and simplify the assembly operation. On the other hand, the elastic-body-receiving slot is constructed in a single housing merely, and none opening of the elastic-body-receiving slot faces the other assembled housing. Moreover, none side of the elastic-body-receiving slot is formed by the other assembled housing. The elastic-body-receiving slot is a non-linear slot. Thus, the purpose of accommodating the elastic body is achieved, the problem of electromagnetic interference leakage of the electronic components disposed on the printed circuit board accommodated within in the housing assembly is effectively avoided, and the EMI shielding is enhanced.

A further object of the present disclosure is to provide an optical transceiver. The housing assembly is formed by an upper cover and a lower cover, and a gasket set is disposed between the upper cover and the lower cover of the housing assembly. Since the gasket set is disposed around the outer periphery of the housing assembly and located at the joint of the upper cover and the lower cover, the problem of electromagnetic interference leakage of the electronic components disposed on the printed circuit board accommodated within in the housing assembly is effectively avoided, and the EMI shielding is enhanced.

In accordance with an aspect of the present disclosure, an optical transceiver is provided and includes a first housing, a second housing, a printed circuit board, a handle member and an elastic body. The first housing includes an elastic-body-receiving slot. The second housing is assembled with the first housing to form a main body including an accommodation space, a first handle-guiding groove and a second handle-guiding groove. The first handle-guiding groove and the second handle-guiding groove are disposed on two opposite sides of the main body, respectively, and neither opening of the elastic-body-receiving slot faces the second housing. The printed circuit board is accommodated within the accommodation space. The handle member includes a first arm and a second arm. The first arm is received within the first handle-guiding groove, and the second arm is received within the second handle-guiding groove. The elastic body is received within the elastic-body-receiving slot and is configured to provide a counterforce when the handle member is subjected to an external force.

In accordance with another aspect of the present disclosure, an optical transceiver is provided and includes a first housing, a second housing, a printed circuit board, a handle member and an elastic body. The first housing includes an elastic-body-receiving slot. The second housing is assembled with the first housing to form a main body including an accommodation space, a first handle-guiding groove and a second handle-guiding groove. The first handle-guiding groove and the second handle-guiding groove are disposed on two opposite sides of the main body, respectively, and each side of the elastic-body-receiving slot is not constructed by the second housing. The printed circuit board is accommodated within the accommodation space. The handle member includes a first arm and a second arm. The first arm is received within the first handle-guiding groove, and the second arm is received within the second handle-guiding groove. The elastic body is received within the elastic-body-receiving slot and is configured to provide a counterforce when the handle member is subjected to an external force.

In accordance with a further aspect of the present disclosure, an optical transceiver is provided and includes a first housing, a second housing, a printed circuit board, a handle member and at least one elastic body. The first housing includes at least one elastic-body-receiving slot. The at least one elastic-body-receiving slot is a non-linear slot. The second housing is assembled with the first housing to form a main body including an accommodation space, a first handle-guiding groove and a second handle-guiding groove. The first handle-guiding groove and the second handle-guiding groove are concavely formed on two opposite sides of the main body, respectively. The printed circuit board is accommodated within the accommodation space and is configured to perform a photoelectric conversion. The handle member includes a first arm and a second arm. The first arm is received within the first handle-guiding groove, and the second arm is received within the second handle-guiding groove. The at least one elastic body is received within the at least one elastic-body-receiving slot and is configured to provide a counterforce when the handle member is subjected to an external force.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1A is an exploded view illustrating an optical transceiver according to a first embodiment of the present disclosure;

FIG. 1B is an exploded view illustrating the optical transceiver according to the first embodiment of the present disclosure and taken from another perspective;

FIG. 1C is a partially disassembled view illustrating the optical transceiver according to the first embodiment of the present disclosure;

FIG. 1D is another partially disassembled view illustrating the optical transceiver according to the first embodiment of the present disclosure;

FIG. 1E is an assembled structure illustrating the optical transceiver according to the first embodiment of the present disclosure;

FIGS. 2A to 2D show an assembling process of the optical transceiver according to the first embodiment of the present disclosure;

FIG. 3A shows the optical transceiver and a corresponding connection slot according to the first embodiment of the present disclosure;

FIG. 3B shows the optical transceiver and the corresponding connection slot assembled together according to the first embodiment of the present disclosure;

FIG. 4A is a cross sectional view illustrating the optical transceiver operated in a locking state according to the first embodiment of the present disclosure;

FIG. 4B is a cross sectional view illustrating the optical transceiver operated in an unlocking state according to the first embodiment of the present disclosure;

FIG. 5 is a perspective structural view illustrating the handle member of the optical transceiver according to the first embodiment of the present disclosure;

FIG. 6 is a partially disassembled view illustrating an optical transceiver according to a second embodiment of the present disclosure;

FIG. 7 is a lateral view illustrating an optical transceiver according to a third embodiment of the present disclosure; and

FIG. 8 is a lateral view illustrating an optical transceiver according to a fourth embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

FIG. 1A is an exploded view illustrating an optical transceiver according to a first embodiment of the present disclosure. FIG. 1B is an exploded view illustrating the optical transceiver according to the first embodiment of the present disclosure and taken from another perspective. FIG. 1C is a partially disassembled view illustrating the optical transceiver according to the first embodiment of the present disclosure. FIG. 1D is another partially disassembled view illustrating the optical transceiver according to the first embodiment of the present disclosure. FIG. 1E is an assembled structure illustrating the optical transceiver according to the first embodiment of the present disclosure. In the embodiment, the optical transceiver 1 is applied to a latching mechanism of for example but not limited to a Quad Small Form-factor Pluggable (QSFP) device and a Quad small form-factor pluggable double density (QSFP-DD) device. The optical transceiver 1 includes a first housing 11, a second housing 12, a printed circuit board 20, a handle member 30 and at least one elastic body 40. Preferably but not exclusively, the first housing 11 and the second housing 12 are an upper cover and a lower cover, respectively, which are formed of a metal material and assembled with each other to form a main body 10 including an accommodation space 13, a first handle-guiding groove 14a and a second handle-guiding groove 14b. The first handle-guiding groove 14a and the second handle-guiding groove 14b are opposite to each other and concavely disposed on two opposite sides 10a and 10b of the main body 10, which is formed by assembling the first housing 11 and the second housing 12. The printed circuit board 20 is accommodated within the accommodation space 13 and configured to perform a photoelectric conversion. In the embodiment, the information required for the photoelectric conversion is transmitted to the printed circuit board 20 from the outside of the first housing 11 and the second housing 12 through an optical fiber 22. The information converted after the photoelectric conversion is outputted through a connection port 21, such as a golden finger of the printed circuit board 20. In the embodiment, the handle member 30 includes a first arm 31a and a second arm 31b, which are made of for example but not limited to a metallic material. The first arm 31a and the second arm 31b spatially corresponds to the first handle-guiding groove 14a and the second handle-guiding groove 14b, respectively. The first arm 31a is received within the first handle-guiding groove 14a. The second arm 31b is received within the second handle-guiding groove 14b. Moreover, preferably but not exclusively, the first arm 31a and the second arm 31b are capable of sliding along the X-axis direction relative to the first handle-guiding groove 14a and the second handle-guiding groove 14b, respectively. In the embodiment, the first housing 11 further includes two elastic-body-receiving slots 15a and 15b. Preferably but not exclusively, the two elastic-body-receiving slots 15a and 15b are concavely formed in the first handle-guiding groove 14a and the second handle-guiding groove 14b, respectively, and configured to receive two elastic bodies 40. The elastic body 40 is configured to provide a counterforce when the handle member 30 is subjected to an external force. In the embodiment, each of the elastic-body-receiving slots 15a and 15b has at least one opening located at the two opposite sides 10a and 10b of the main body 10, which is formed by assembling the first housing 11 and the second housing 12. In the embodiment, none opening of the elastic-body-receiving slots 15a and 15b faces the second housing 12, and none side of the elastic-body-receiving slots 15a, 15b is constructed by the second housing 12. Preferably but not exclusively, the two elastic bodies 40 are telescopic springs, which are detachably connected to the first arm 31a and the second arm 31b of the handle member 30, respectively, so as to construct an elastic restoring force for the latch mechanism. Notably, the first arm 31a and the second arm 31b of the handle member 30 are disposed outside the first housing 11 and the second housing 12, but do not penetrate the first housing 11 and the second housing 12. Thus, the problem of electromagnetic interference leakage of the electronic components disposed on the printed circuit board 13 accommodated within in the first housing 11 and the second housing 12 is effectively avoided, and the EMI shielding is enhanced.

In the embodiment, the handle member 30 further includes a holding portion 36 and a connection portion 35. The connection portion 35 is connected to the holding portion 36, the first arm 31a and the second arm 30b. Preferably but not exclusively, in the sliding direction of the first arm 31a and the second arm 31b relative to the first handle-guiding groove 14a and the second handle-guiding groove 14b, which is in the X-axis direction, the connection portion 35 and the holding portion 36 are misaligned with each other. In the embodiment, the connection portion 35 has a horizontal part arranged at a horizontal level different from that of the holding portion 36. Preferably but not exclusively, in the embodiment, the first arm 31a and the second arm 31b have symmetrical structures to each other. In the embodiment, the first arm 31a further includes an opening 33a and a limitation portion 34a, and the second arm 31b further includes an opening 33b and a limitation portion 34b. Taking the first arm 31a as an example, the opening 33a of the first arm 31a spatially corresponds to the elastic-body-receiving slot 15a and is in communication with the elastic-body-receiving slot 15a, so that it facilitates the elastic body 40 to be placed into the elastic-body-receiving slot 15a through the opening 33a. The limitation portion 34a of the first arm 31a is disposed adjacent to the opening 33a, and is extended from the first arm 31a toward the elastic-body-receiving slot 15a, such as along the Y-axis direction. When the elastic body 40 is received within the elastic-body-receiving slot 15a, the limitation portion 34a of the first arm 31a is in contact with the elastic body 40, and is pushed by an elastic force of the elastic body 40. Similarly, when the elastic body 40 is received within the elastic-body-receiving slot 15b, the limitation portion 34b of the second arm 31b is in contact with the elastic body 40, and is pushed by an elastic force of the elastic body 40. Thus, the elastic bodies 40 and the first arm portion 31a and the second arm 31b of the handle member 30 are configured to provide the elastic restoring force for the latch mechanism.

In the embodiment, two elastic-body-receiving slots 15a and 15b further includes two guiding grooves 16a and 16b, respectively. Taking the elastic-body-receiving slot 15a as an example, preferably but not exclusively, the guiding groves 16a is vertical to the elastic-body-receiving slot 15a and is in communication with the elastic-body-receiving slot 15a. It facilitates the limitation portion 34a of the first arm 31a to be disposed in the elastic-body-receiving slot 15a. FIGS. 2A to 2D show an assembling process of the optical transceiver according to the first embodiment of the present disclosure. Firstly, for assembling the optical transceiver 1, the printed circuit board 20 is accommodated within the accommodation space 13 on the first housing 11, as shown in FIG. 2A. Then, the limitation portion 34a of the first arm 31a is aligned to the guiding groove 16a, and slid into the elastic-body-receiving slot 15a along for example but not limited to the Z axis direction, as shown in FIG. 2B. At the same time, the limitation portion 34b of the second arm 31b is aligned to the guiding groove 16b, and slid into the elastic-body-receiving slot 15b. Thereafter, the handle member 30 is rotated, so that the handle member 30 is preset on the first housing 11. Notably, the connection manner of the optical fiber 22 of the printed circuit board 20 is not limited in the present disclosure. Preferably but not exclusively, the optical fiber 22 is detachably connected after the handle member 30 is preset on the first housing 11. In other embodiments, the optical fiber 22 can be for example but not limited to an LC connector, which is capable of being connected after the optical transceiver 1 is assembled. The present disclosure is not limited thereto and not redundantly described herein. In the embodiment, after the handle member 30 is preset on the first housing 11, the second housing 12 is assembled with the first housing 11, so that the first handle-guiding groove 14a and the second handle-guiding groove 14b are formed on two opposite sides 10a and 10b of the main body 10, respectively. In that, the first arm 31a and the second arm 31b are received within the first handle-guiding groove 14a and the second handle-guiding groove 14b, respectively, as shown in FIG. 2C. Finally, the elastic body 40 is placed into the elastic-body-receiving slot 15a through the opening 33a of the first arm 31a, as shown in FIG. 3D. At the same time, the elastic body 40 is placed into the elastic-body-receiving slot 15b through the opening 33b of the second arm 31b. Thus, the assembly of the optical transceiver 1 is completed. Certainly, the assembling method of the optical transceiver 1 of the present disclosure is not limited thereto.

FIG. 3A shows the optical transceiver and a corresponding connection slot according to the first embodiment of the present disclosure. FIG. 3B shows the optical transceiver and the corresponding connection slot assembled together according to the first embodiment of the present disclosure. In the embodiment, the optical transceiver 1 is applied to an optical fiber communication system, and is matched with a connection slot 9. Preferably but not exclusively, the optical transceiver 1 is plugged into or detached from the connection slot 9 in the X-axis direction. In the embodiment, the connection slot 9 includes a slot opening 91 and an accommodation portion 92. While the optical transceiver 1 is plugged into the accommodation portion 92 through the slot opening 91, the connection port 21 of the printed circuit board 20 is electrically connected to the connection circuit disposed within the connection slot 9, so that the electrical connection is achieved to transmit the information converted after the photoelectric conversion. It is not an essential feature to limit the present disclosure, and not redundantly described herein. Notably, in the embodiment, the first arm 31a further includes a first engagement portion 32a. Preferably but not exclusively, the first engagement portion 32a is disposed on the front end of the first arm 31a. Similarly, the second arm 31b further includes a first engagement portion 32b disposed on the front end of the second arm 31b. In the embodiment, the connection slot 9 includes at least two second engagement portions 93, disposed on two opposite inner walls thereof. Taking the first engagement portion 32a of the first arm 31a as an example, the first engagement portion 32a spatially corresponds to the second engagement portion 93 of the connection slot 9. In the embodiment, while the optical transceiver 1 is plugged into the accommodation portion 92, the first engagement portions 32a and 32b are engaged with the corresponding second engagement portions 93, respectively. Thus, it avoids the optical transceiver 1 to be detached for the connection slot 9, as shown in FIG. 3B.

FIG. 4A is a cross sectional view illustrating the optical transceiver operated in a locking state according to the first embodiment of the present disclosure. FIG. 4B is a cross sectional view illustrating the optical transceiver operated in an unlocking state according to the first embodiment of the present disclosure. Please refer to FIGS. 3A and 3B and FIGS. 4A and 4B. In the embodiment, the limitation portion 34a of the first arm 31a and the limitation portion 34b of the second arm 31b are pushed by the elastic force of the two elastic bodies 40, respectively. In that, the first arm 31a and the second arm 31b of the handle member 30 are moved relative to the first handle-guiding groove 14a and the second handle-guiding groove 14b and slid to a first position, as shown in FIG. 4A. Due to the constant pushing of the elastic body 40, when a user plugs the optical transceiver 1 into the accommodation portion 92 of the connection slot 9, the first engagement portions 32a and 32b are engaged with the corresponding second engagement portions 93, respectively. It avoids the optical transceiver 1 to be detached from the connection slot 9. On the other hand, preferably but not exclusively, the user can pull the holding portion 36 of the handle member 30 to detach the optical transceiver 1 from the connection slot 9. When the holding portion 36 of the handle member 30 is forced to drive the limitation portion 34a of the first arm 31a and the limitation portion 34b of the second arm 31b against the elastic force of the at least two elastic bodies 40, the first arm 31a and the second arm 31b of the handle member 30 are moved relative to the first handle-guiding groove 14a and the second handle-guiding groove 14b and slid to a second position, as shown in FIG. 4B. In that, the first engagement portions 32a and 32b are misaligned to the corresponding second engagement portions 93 and are not engaged with each other. Thus, the optical transceiver 1 can be detached from the connection slot 9.

Notably, in the embodiment, a spacing distance D is formed between the opening 33a and limitation portion 34a of the first arm 31a in a direction of sliding the first arm 31a relative to the first handle-guiding groove 14a, for example along the X-axis direction. It is advantageous to prevent the elastic body 40 from bouncing out from the elastic-body-receiving slot 15a after the elastic body 40 is received within the elastic-body-receiving slot 15a. Similarly, a spacing distance D is formed between the opening 33b and limitation portion 34b of the second arm 31b in a direction of sliding the second arm 31b relative to the second handle-guiding groove 14b, for example along the X-axis direction. It is advantageous to prevent the elastic body 40 from bouncing out from the elastic-body-receiving slot 15b after the elastic body 40 is received within the elastic-body-receiving slot 15b. In other words, a spacing distance D is formed between the opening 33a and the limitation portion 34a, or a spacing distance D is formed between the opening 33b and the limitation portion 34b, in a direction of sliding the handle member 30.

FIG. 5 is a perspective structural view illustrating the handle member of the optical transceiver according to the first embodiment of the present disclosure. It is noted that, in the sliding direction of the first arm 31a and the second arm 31b relative to the first handle-guiding groove 14a and the second handle-guiding groove 14b, which is in the X-axis direction, the connection portion 35 and the holding portion 36 are misaligned with each other. Namely, the connection portion 35 has a horizontal part arranged at a horizontal level different from that of the holding portion 36. Accordingly, in the embodiment, when the user pulls the holding portion 36 of the handle member 30, the movement of the handle member 30 does not interfere with the optical fiber 22 connected to the printed circuit board 20 in the sliding direction. Even if the connection of the optical fiber 22 is fastened on the upper cover of the second housing 12 through for example the LC connector, when the user pulls the holding portion 36 of the handle member 30, the handle member 30 is driven to move without interference in the sliding direction.

FIG. 6 is a partially disassembled view illustrating an optical transceiver according to a second embodiment of the present disclosure. In the embodiment, the structures, elements and functions of the optical transceiver 1 are similar to those of the optical transceiver 1 in FIGS. 1A to 1E. The elements and features indicated by the numerals similar to those of the first embodiment mean similar elements and features, and are not redundantly described herein. In the embodiment, the optical transceiver 1 further includes a gasket set 17. Preferably but not exclusively, the gasket set is N-shaped, and is disposed between the first housing 11 and the second housing 12. In other embodiment, the arrangement and position of the gasket set 17 is adjustable according to the practical requirements. With the gasket set 17 disposed around the periphery of the housing assembly formed by the first housing 11 and the second housing 12 and located at the joint of the upper cover and the lower cover, the problem of electromagnetic interference leakage of the electronic components disposed on the printed circuit board 20 accommodated within in the housing assembly is effectively avoided, and the EMI shielding is enhanced.

FIG. 7 is a lateral view illustrating an optical transceiver according to a third embodiment of the present disclosure. In the embodiment, the structures, elements and functions of the optical transceiver 1 are similar to those of the optical transceiver 1 in FIGS. 1A to 1E. The elements and features indicated by the numerals similar to those of the first embodiment mean similar elements and features, and are not redundantly described herein. In the embodiment, the guiding groove 16a of the elastic-body-receiving slot 15a is further designed to be inclined relative to the elastic-body-receiving slot 15a. With the guiding groove 16a in communication with the elastic-body-receiving slot 15a, the limiting portion 34a of the first arm 31a is slid along the guiding groove 16a, and then disposed in the elastic-body-receiving slot 15a.

FIG. 8 is a lateral view illustrating an optical transceiver according to a fourth embodiment of the present disclosure. In the embodiment, the structures, elements and functions of the optical transceiver 1 are similar to those of the optical transceiver 1 in FIGS. 1A to 1E. The elements and features indicated by the numerals similar to those of the first embodiment mean similar elements and features, and are not redundantly described herein. In the embodiment, the guiding groove 16a of the elastic-body-receiving slot 15a is further designed to be curved relative to the elastic-body-receiving slot 15a. With the guiding groove 16a in communication with the elastic-body-receiving slot 15a, the limiting portion 34a of the first arm 31a is slid along the guiding groove 16a, and then disposed in the elastic-body-receiving slot 15a.

Notably, the communication manner of the guiding groove 16a and the elastic-body-receiving slot 15a or the communication manner of the guiding groove 16b and the elastic-body-receiving slot 15b is not limited in the present disclosure. For the purpose of enhancing the protection of electromagnetic interference, none opening of the combination of the guiding groove 16a and the elastic-body-receiving slot 15a or the guiding groove 16b and the elastic-body-receiving slot 15b faces the second housing 12, and none side of above-mentioned combination is formed by the second housing 12. In addition, the elastic-body-receiving slot 15a is combined with the guide groove 16a to form a nonlinear-shaped slot, or the elastic-body-receiving slot 15b is combined with the guide groove 16b to form a nonlinear-shaped slot. In other words, the shape of the elastic-body-receiving slots 15a and 15b is one selected from one of the group consisting of an inline type, a C type, an L type, a T type and a combination thereof. It is adjustable according to the practical requirements. Notably, the combination of the guiding groove 16a and the elastic-body-receiving slot 15a or the guiding groove 16b and the elastic-body-receiving slot 15b has no opening facing to the second housing 12. Namely, none opening of the elastic-body-receiving slots 15a and 15b faces the second housing 12. Moreover, none side of the elastic-body-receiving slots 15a and 15b is formed by the second housing 12. Under the condition, the effect of enhancing the protection of electromagnetic interference is not affected. It is not redundantly described hereafter.

In summary, the present disclosure provides an optical transceiver. By disposing a latch handle member on the outer side of a housing without penetrating the housing assembly, it is beneficial to prevent the electronic components disposed on the printed circuit board accommodated within the housing assembly from generating the electromagnetic interference (EMI) leakage, so that EMI shielding is enhanced. An elastic body providing the elastic force in the latching mechanism is installed through an opening of the latch handle member into an elastic-body-receiving slot constructed by the latch handle member and the housing assembly. The elastic body is effectively limited in the elastic-body-receiving slot. It is beneficial to prevent the elastic body from bouncing out during the latching operation, and simplify the assembly operation. On the other hand, the elastic-body-receiving slot is constructed in a single housing merely, and none opening of the elastic-body-receiving slot faces the other assembled housing. Moreover, none side of the elastic-body-receiving slot is formed by the other assembled housing. The elastic-body-receiving slot is a non-linear slot. Thus, the purpose of accommodating the elastic body is achieved, the problem of electromagnetic interference leakage of the electronic components disposed on the printed circuit board accommodated within in the housing assembly is effectively avoided, and the EMI shielding is enhanced. In addition, the housing assembly is formed by an upper cover and a lower cover, and a gasket set is disposed between the upper cover and the lower cover of the housing assembly. Since the gasket set is disposed around the outer periphery of the housing assembly and located at the joint of the upper cover and the lower cover, the problem of electromagnetic interference leakage of the electronic components disposed on the printed circuit board accommodated within in the housing assembly is effectively avoided, and the EMI shielding is enhanced.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An optical transceiver comprising:
a first housing comprising an elastic-body-receiving slot;
a second housing assembled with the first housing to form a main body comprising an accommodation space, a first handle-guiding groove and a second handle-guiding groove, wherein the first handle-guiding groove and the second handle-guiding groove are disposed on two opposite sides of the main body, respectively, and none opening of the elastic-body-receiving slot faces the second housing;
a printed circuit board accommodated within the accommodation space;
a handle member comprising a first arm and a second arm, wherein the first arm is received within the first handle-guiding groove, and the second arm is received within the second handle-guiding groove; and
an elastic body received within the elastic-body-receiving slot and configured to provide a counterforce when the handle member is subjected to an external force.

2. The optical transceiver according to claim 1, wherein the handle member comprises:
a holding portion; and
a connection portion connected to the holding portion, the first arm and the second arm, wherein the connection portion has a horizontal part arranged at a horizontal level different from that of the holding portion.

3. The optical transceiver according to claim 1, wherein each of the first arm and the second arm comprises:
an opening spatially corresponding to the elastic-body-receiving slot and exposing a part of the elastic-body-receiving slot; and
a limitation portion disposed adjacent to the opening and in contact with the elastic body.

4. The optical transceiver according to claim 3, wherein a spacing distance is formed between the opening and the limitation portion in a direction of sliding the handle member.

5. The optical transceiver according to claim 3, wherein each of the elastic-body-receiving slot further comprises a guiding groove in communication with the elastic-body-receiving slot, so that the limitation portion is disposed in the elastic-body-receiving slot.

6. The optical transceiver according to claim 1, wherein the shape of the elastic-body-receiving slot is one selected from one of the group consisting of an inline type, a C type, an L type, a T type and a combination thereof.

7. The optical transceiver according to claim 1, further comprising a gasket set disposed between the first housing and the second housing.

8. An optical transceiver comprising:
a first housing comprising an elastic-body-receiving slot;
a second housing assembled with the first housing to form a main body comprising an accommodation space, a first handle-guiding groove and a second handle-guiding groove, wherein the first handle-guiding groove and the second handle-guiding groove are disposed on two opposite sides of the main body, respectively, and none side of the elastic-body-receiving slot is constructed by the second housing;
a printed circuit board accommodated within the accommodation space;
a handle member comprising a first arm and a second arm, wherein the first arm is received within the first handle-guiding groove, and the second arm is received within the second handle-guiding groove; and
an elastic body received within the elastic-body-receiving slot and configured to provide a counterforce when the handle member is subjected to an external force.

9. The optical transceiver according to claim 8, wherein the handle member comprises:
a holding portion; and
a connection portion connected to the holding portion, the first arm and the second arm, wherein the connection portion has a horizontal part arranged at a horizontal level different from that of the holding portion.

10. The optical transceiver according to claim 8, wherein each of the first arm and the second arm comprises:
an opening spatially corresponding to the elastic-body-receiving slot and exposing a part of the elastic-body-receiving slot; and
a limitation portion disposed adjacent to the opening and in contact with the elastic body.

11. The optical transceiver according to claim 10, wherein a spacing distance is formed between the opening and the limitation portion in a direction of sliding the handle member.

12. The optical transceiver according to claim 10, wherein each of the elastic-body-receiving slot further comprises a guiding groove in communication with the elastic-body-receiving slot, so that the limitation portion is disposed in the elastic-body-receiving slot.

13. The optical transceiver according to claim 8, further comprising a gasket set disposed between the first housing and the second housing.

14. An optical transceiver comprising:
a first housing comprising at least one elastic-body-receiving slot, wherein the at least one elastic-body-receiving slot is a non-linear slot;
a second housing assembled with the first housing to form a main body comprising an accommodation space, a first handle-guiding groove and a second handle-guiding groove, wherein the first handle-guiding groove and the second handle-guiding groove are concavely formed on two opposite sides of the main body, respectively;
a printed circuit board accommodated within the accommodation space and configured to perform a photoelectric conversion;
a handle member comprising a first arm and a second arm, wherein the first arm is received within the first handle-guiding groove, and the second arm is received within the second handle-guiding groove; and
at least one elastic body received within the at least one elastic-body-receiving slot and configured to provide a counterforce when the handle member is subjected to an external force.

15. The optical transceiver according to claim 14, wherein the handle member comprises:
a holding portion; and
a connection portion connected to the holding portion, the first arm and the second arm, wherein the connection portion has a horizontal part arranged at a horizontal level different from that of the holding portion.

16. The optical transceiver according to claim 14, wherein each of the first arm and the second arm comprises:
an opening spatially corresponding to the elastic-body-receiving slot and exposing a part of the elastic-body-receiving slot; and
a limitation portion disposed adjacent to the opening and in contact with the elastic body.

17. The optical transceiver according to claim 16, wherein a spacing distance is formed between the opening and the limitation portion in a direction of sliding the handle member.

18. The optical transceiver according to claim 16, wherein each of the at least one elastic-body-receiving slot further comprises a guiding groove in communication with the elastic-body-receiving slot, so that the limitation portion is disposed in the elastic-body-receiving slot.

19. The optical transceiver according to claim 14, further comprising a gasket set disposed between the first housing and the second housing.
